(19) United States
(12) Patent Application Publication
(10) Pub. No.: US 2009/0067142 A1
(43) Pub. Date: Mar. 12, 2009

(54) RETAINING MECHANISM FOR CIRCUIT CARD

(75) Inventors: HO-CHIN TSAI, Tu-Cheng (TW); LI-PING CHEN, Tu-Cheng (TW); SHENG-HUNG LEE, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/869,757

(22) Filed: Oct. 10, 2007

(30) Foreign Application Priority Data
Sep. 6, 2007 (CN) 200720200974.X

(51) Int. Cl. H05K 7/12; H05K 5/02

(52) U.S. Cl. 361/759; 361/752; 439/260

(57) ABSTRACT

A retaining mechanism for retaining a circuit card includes a chassis (10), and a retaining member (80). The chassis has a front panel (14) and an opposite back panel (16). The front panel is configured for mounting a first edge of the circuit card thereon. The retaining member is pivotably attached to the back panel, and the retaining member defines a traversing securing slot (84) for receiving a second edge of the circuit card opposite to the first edge. The retaining member has a resilient hook (80) for detachably engaging with the back panel.

### BACKGROUND

1. Field of the Invention

The present invention relates to a retaining mechanism for a circuit card, particularly to a retaining mechanism for retaining a circuit card in a server.

2. Description of Related Art

Nowadays, printed circuit cards are used in many electronic devices, such as computers and telecommunications equipment. In these devices, printed circuit cards are often electrically connected to a main circuit board using connectors that extend from the printed circuit card that mate with connectors located on the main circuit board.

In conventional personal computers (PC's), for example, the main circuit board is generally referred to as the motherboard. The electrical connector located on the motherboard in a PC is generally referred to as a card slot and can receive a variety of printed circuit cards that support, among other things, video displays, serial interface ports, parallel interface ports, computer memory (RAM) and additional data storage.

Printed circuit cards are usually held in place with a fastening means, such as a screw, or a mounting device installed at one end of the card. Even with this fastening means, printed circuit cards are very sensitive to motion and a small degree of motion can dislodge a card and result in equipment malfunction.

What is needed, therefore, is a retaining mechanism for sturdily and reliably retaining a circuit card in position on a main circuit board, and is easy to engage and disengage.

### SUMMARY

A retaining mechanism for retaining a circuit card includes a chassis, and a retaining member. The chassis has a front panel and an opposite back panel. The front panel is configured for mounting a front edge of the circuit card thereon. The retaining member is pivotably attached to the back panel, and the retaining member defines a traversing securing slot for receiving a second edge of the circuit card opposite to the first edge. The retaining member has a resilient hook for detachably engaging with the back panel.

Other advantages and novel features of the present invention will become more apparent from the following detailed description of a preferred embodiment when taken in conjunction with the accompanying drawings, in which:

### BRIEF DESCRIPTION OF THE DRAWINGS

FIG. 1 is a partially exploded, isometric view of a retaining mechanism for a circuit card according to a preferred embodiment of the present invention, the retaining mechanism including a chassis, and a retaining member;

FIG. 2 is an enlarged view of the retaining member of the retaining mechanism of FIG. 1;

FIG. 3 is an isometric, assembled view of FIG. 1, but shown from another aspect; and

FIG. 4 is similar to FIG. 3, but the circuit card being retained by the retaining member.

### DETAILED DESCRIPTION OF THE EMBODIMENT

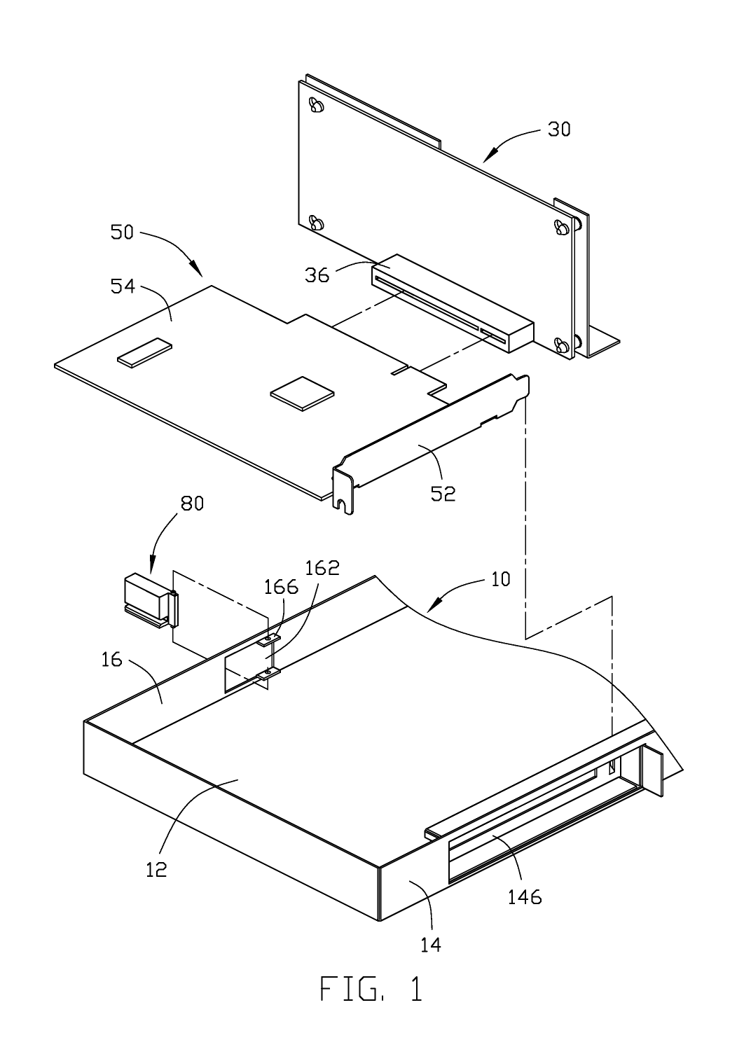

Referring to FIG. 1, a retaining mechanism of a preferred embodiment of the present invention for a circuit card 50 includes a chassis 10 for receiving the circuit card 50, and a retaining member 80 for retaining the circuit card 50. According to this embodiment of the present invention, a transfer card 30 is provided for electrically connecting to the circuit card 50, so that the circuit card 50 can be horizontally placed in the chassis 10.

The chassis 10 has a bottom panel 12, a front panel 14 and a back panel 16. The front panel 14 and the back panel 16 are perpendicularly formed on the bottom panel 12. A receiving portion 146 is formed inward on the front panel 14. A rectangular opening 162 is defined in the back panel 16. A pair of tabs 166 is formed on the back panel 16 respectively adjacent to opposite sides of the opening 162. Each tab 166 defines a pivot hole therein.

The transfer card 30 has an electrical connector 36 for receiving a connecting portion extending from an edge of the circuit card 50. The circuit card 50 includes a printed circuit board 54 and a cover 52 fixed to another adjacent edge of the printed circuit board 54.

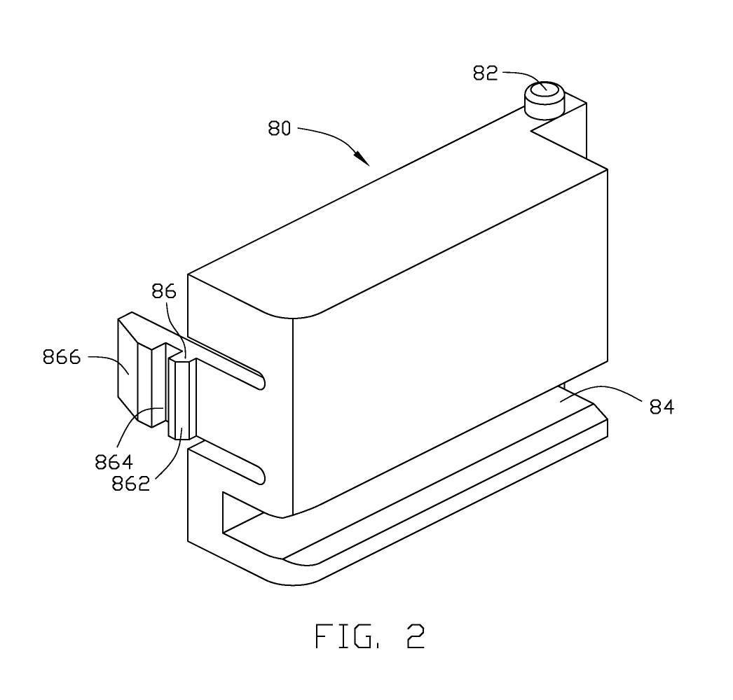

Referring also to FIG. 2, the retaining member 80 has a pair of pivot portions 82 at opposite sides of one end thereof, and a resilient hook 86 formed at the other end thereof. The hook 86 has a wedge-shaped guiding portion 862, and a locking slot 864 is defined behind the guiding portion 862. A pressing portion 866 is formed at an end of the hook 86. A retaining slot 84 is defined traversing a side of the retaining member 80 from one end to the other for holding the printed circuit board 54 of the circuit card 50.

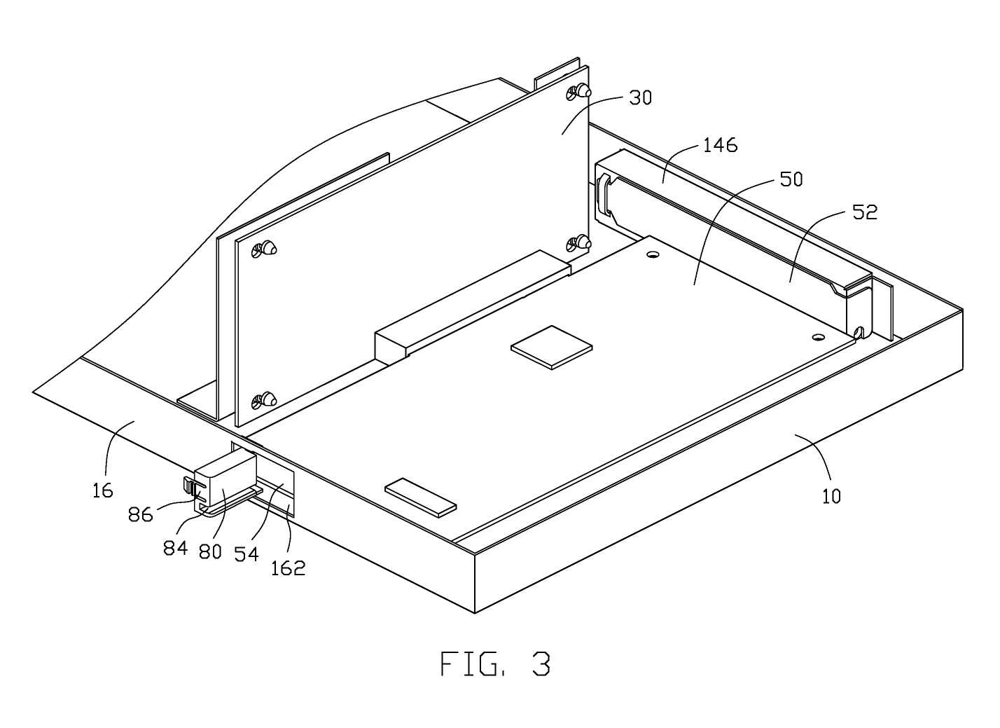

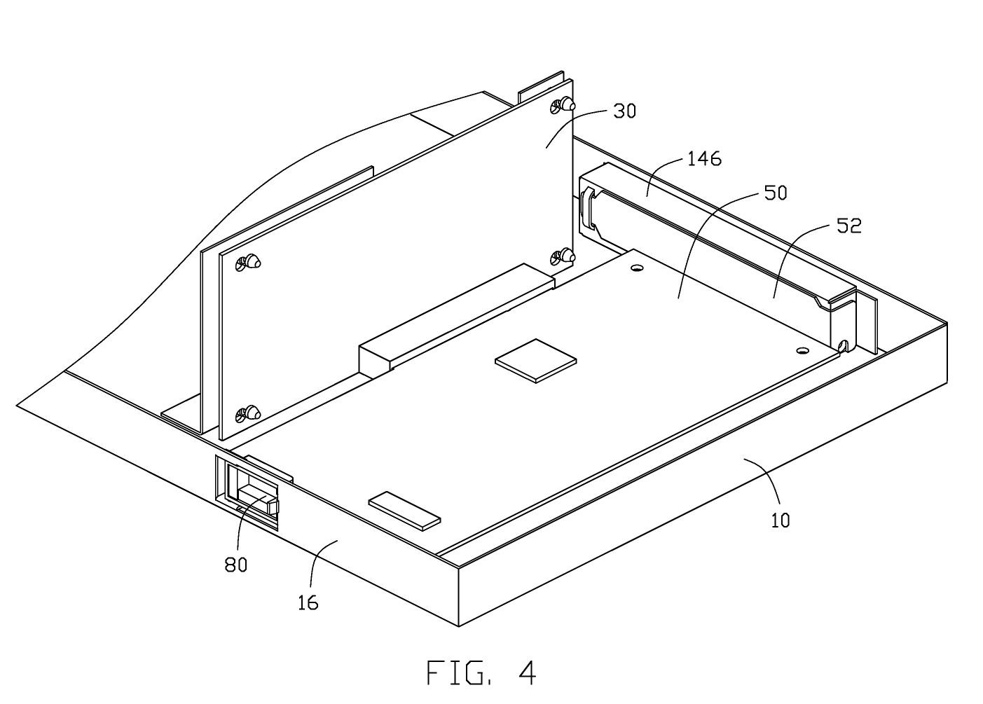

Referring to FIG. 3 and FIG. 4, when retaining the circuit card 50, the transfer card 30 is firstly mounted in the chassis 10. The circuit card 50 is inserted into the connector 36 of the transfer card 30 from a sideward direction and the cover 52 of the circuit card 50 is mounted to the receiving portion 146. The pivot portions 82 of the retaining member 80 are pivotably received in the pivot holes of the tabs 166 of the chassis 10. The retaining member 80 is rotatable from the outer side of the back panel 16 to the inner side thereof. The edge at an opposite side of the printed circuit board 54 to the cover 52 is retained in the retaining slot 84 of the retaining member 80 when the retaining member 80 is to the inner side of the chassis 10. The hook 86 is then resiliently deformed to engage the back panel 16 in the locking slot 864. In this manner then, the circuit card 50 is securely mounted in the chassis 10.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A retaining mechanism for retaining a circuit card comprising:
a chassis having a front panel and an opposite back panel, the front panel being configured for mounting a first edge of the circuit card thereon; and
a retaining member pivotably attached to the back panel, and the retaining member defining a traversing securing slot for receiving a second edge of the circuit card opposite to the first edge, the retaining member having a resilient hook for detachably engaging with the back panel.

2. The retaining mechanism as described in claim 1, further comprising a transfer card for electrically connection to the circuit card, and the transfer card is perpendicularly mounted in the chassis.

3. The retaining mechanism as described in claim 1, wherein the hook comprises a wedge-shaped guiding portion, and a locking slot is defined behind the guiding portion for engaging with the back panel.

4. The retaining mechanism as described in claim 3, wherein the hook further comprises a pressing portion at a distal end thereof for deformably disengaging the hook from the back panel.

5. The retaining mechanism as described in claim 4, wherein the back panel defines an opening for the retaining member rotating therethrough, the locking slot of the retaining member snappingly engages with the back panel at the opening, and the pressing portion is exposed outside the opening.

6. The retaining mechanism as described in claim 5, wherein the retaining member is pivotably connected to a pair of tabs, and the tabs are formed adjacent to the opening.

7. The retaining mechanism as described in claim 1, wherein the circuit card comprises a cover at the first edge thereof for engaging with a receiving portion, and the receiving portion is formed at an inner side of the front panel.

8. A circuit card retaining assembly comprising:
a chassis having a front panel and an opposite back panel, the front panel having a receiving portion, the back panel defining an opening;
a circuit card having a printed circuit board and a cover fixed to an edge of the printed circuit board, the cover mounted to the receiving portion of the front panel;
a retaining member pivotably attached to the back panel, the retaining member defining a securing slot, the retaining member being rotatable through the opening of the back panel, the printed circuit card being receivable in the securing slot.

9. The circuit card retaining assembly as described in claim 8, further comprising a transfer card for electrically receiving the circuit card, and the transfer card is perpendicularly mounted in the chassis.

10. The circuit card retaining assembly as described in claim 8, wherein the retaining member has a resilient hook for locking the retaining member in position, and the circuit card is received in and held in position by the securing slot.

11. The circuit card retaining assembly as described in claim 10, wherein the hook comprises a wedge-shaped guiding portion and a locking slot is defined behind the guiding portion for engaging with the back panel.

12. The circuit card retaining assembly as described in claim 11, wherein the hook further comprises a pressing portion at a distal end thereof for deformably disengaging the hook from the back panel.

13. The circuit card retaining assembly as described in claim 12, wherein the locking slot of the retaining member snappingly engages with a portion of the back panel at the opening, and the pressing portion is exposed outside the opening.

14. The circuit card retaining assembly as described in claim 8, wherein the retaining member is pivotably connected to a pair of tabs, and the tabs are formed on the back panel adjacent to the opening.

15. A circuit board assembly comprising:
a chassis having a bottom panel, a front panel and an opposite back panel, the front and back panels being perpendicularly extending from the bottom panel;
a printed circuit board parallel to the bottom panel, the printed circuit board having a first edge, an opposite second edge, and a third edge connected between the first and second edges, the printed circuit board having an edge connector arranged on the third edge, the first edge being securely coupled to the front panel; and
a transfer card mounted on the bottom panel, the transfer card having a socket connector with the edge connector of the printed circuit board inserted therein;
a retaining member attached to the back panel, the retaining member being rotatable about an axis relative to the back panel, the retaining member having a retaining slot with the second edge of the printed circuit board received therein, and a resilient hook being distally formed opposite to the axis for detachably engaging with the back panel.

16. The circuit board assembly as described in claim 15, wherein the retaining slot of the retaining member extends perpendicular to the axis.
